(19) United States
(12) Patent Application Publication
(10) Pub. No.: US 2008/0138723 A1
(43) Pub. Date: Jun. 12, 2008

(54) METHOD OF FABRICATING COLOR FILTER USING INK-JET TECHNIQUE

(75) Inventors: Sang-il Kim, Suwon-si (KR); Woo-sik Kim, Seoul (KR)

Correspondence Address: STANZIONE & KIM, LLP, 919 18TH STREET, N.W., SUITE 440, WASHINGTON, DC, 20006, US

(73) Assignee: Samsung Electronics Co., Ltd., Suwon-si (KR)

(21) Appl. No.: 11/776,051

(22) Filed: Jul. 11, 2007

(30) Foreign Application Priority Data
Dec. 8, 2006 (KR) 2006-125080

(51) Int. Cl. G03F 1/06

(52) U.S. Cl. 430/7

(57) ABSTRACT

A method of fabricating a color filter using an ink-jet technique. The method includes inclining an ink-jet head having a plurality of nozzles at a predetermined angle, moving the ink-jet head in a lengthwise direction of the color filter that is divided into a plurality of working regions, ejecting color ink into a plurality of pixels, moving the ink-jet head to another adjacent working region after work in a predetermined working region is completed, and ejecting color ink, wherein the ink-jet head passes over a working region in which all of the nozzles of the ink-jet head operate and color ink is ejected through each of the nozzles and when the ink-jet head leaves the working region so that color ink is ejected into the pixels by less than all of the plurality of nozzles, all of the nozzles continue to operate.

### CROSS-REFERENCE TO RELATED APPLICATIONS

This application claims the benefit of Korean Patent Application No. 10-2006-0125080, filed on Dec. 8, 2006 in the Korean Intellectual Property Office, the disclosure of which incorporated herein in its entirety by reference.

### BACKGROUND OF THE INVENTION

1. Field of the Invention

The present general inventive concept relates to a method of fabricating a color filter, and more particularly, to a method of fabricating a color filter using an ink-jet technique.

2. Description of the Related Art

Recently, flat display devices, such as a liquid crystal display (LCD), which increases the size of a screen to display information from a TV and a computer, a plasma display panel (PDP), an organic electro luminescence (EL) displays, a light emitting diode (LED), and a field emission display (FED) are being used. From these flat display devices, LCDs, which are mainly used for a computer monitor and a notebook PC or the like due to low power consumption, have been spotlighted.

A color filter, which forms an image of a desired color by passing white light modulated by a liquid crystal layer, is disposed on an LCD. The color filter has the structure in which a plurality of red (R), green (G), and blue (B) pixels are arranged on a transparent substrate to have a predetermined shape. Methods of fabricating a color filter include a dyeing method, a pigment dispersion method, a printing method, and electrodeposition method or the like.

However, in the methods of fabricating a color filter as listed-above, a predetermined process must be repeatedly performed according to each color so as to form red (R), green (G), and blue (B) pixels, and thus, a process efficiency is lowered and fabrication costs increase.

Thus, a method of fabricating a color filter using an ink-jet technique by which a fabrication process is simplified and fabrication costs are reduced has been proposed. In such a method of fabricating a color filter using an ink-jet technique, ink droplets of predetermined colors such as red (R), green (G), and blue (B) are ejected into each pixel region of a substrate through nozzles of an ink-jet head, and thereby, forming a pixel of a predetermined color.

FIG. 1 illustrates an example of a method of fabricating a color filter by ejecting ink into each pixel of a color filter 10 using a conventional ink-jet head 20, FIG. 2 illustrates the color filter 10 fabricated by the method of FIG. 1 that is divided into regions according to ink thickness, FIG. 3 is a graph illustrating an ink thickness taken along line I-I′ of FIG. 2, and FIG. 4 is a graph illustrating an ink thickness taken along line II-II′ of FIG. 2.

Referring to FIG. 1, the conventional ink-jet head 20 comprising first through fourth nozzles 21, 22, 23, and 24 ejects ink into each pixel 11 by passing an upper portion of the color filter 10 in a certain direction (Y-direction) while the conventional ink-jet head 20 is inclined at a predetermined angle with respect to the color filter 10. The conventional ink-jet head 20 moves in an X-direction and then moves in a Y-direction while ejecting ink into each pixel 11. By repeatedly performing such a process, the pixels 11 of the color filter 10 are filled with ink.

However, as the conventional ink-jet head 20 moves while inclined at a predetermined angle with respect to the color filter 10, a difference in the amount of ink ejected through the first through fourth nozzles 21, 22, 23, and 24 occurs according to the number of nozzles for ejecting ink in a predetermined region in which the conventional ink-jet head 20 passes over and leaves the color filter 10.

Referring to FIGS. 2 and 3, the amount of ink ejected through a first nozzle 21 decreases in region 1 along the Y-direction and a predetermined amount of ink is ejected in region 2 along the Y-direction. However, ink ejected through the fourth nozzle 24 is ejected in region 2 to a predetermined thickness along the Y-direction and the amount of ink gradually increases in region 3 along the Y-direction.

This is because the number of nozzles passing each region (region 1, 2, and 3) is different as the conventional ink-jet head 20 moves in the Y-direction. In detail, in region 2, all of the first through fourth nozzles 21, 22, 23, and 24 operate and ink is ejected through the four nozzles. However, in region 1, the number of nozzles for ejecting ink gradually increases as the first nozzle 21 to the third nozzle 23 sequentially passes over region 1 of the color filter 10, and in region 3, the number of nozzles for ejecting ink is gradually reduced as the third nozzle 23 to the first nozzle 21 sequentially leave region 3 of the color filter 10. Thus, the amount of ink ejected in region 1 and region 3 is larger than the amount of ink ejected in region 2.

Referring to FIGS. 2 and 4, a fin 13 in which an ink thickness rapidly increases is formed at a boundary 12 of the conventional ink-jet head 20 along the X-direction. This is because the ink thickness of the boundary 12 is increased when a working section of the conventional ink-jet head 20 varies along the X-direction.

Hence, since cross-talk between an operating nozzle and an non-operating nozzle from the first through fourth nozzles 21, 22, 23, and 24 occurs, a difference in the amount of ink ejected occurs according to the number of other simultaneously-operating adjacent nozzles. However, the reverse case may occur.

In this way, due to interference between the operating and non-operating nozzles, a difference in the amount of ink ejected through one of the first through fourth nozzles 21, 22, 23, and 24 causes a difference in an ink thickness of a pixel, and due to the non-uniformity of ink thickness in a partial region of the color filter 10, the reliability of color reproduction is lowered and a perception of color by a viewer is reduced.

### SUMMARY OF THE INVENTION

The present general inventive concept provides a method of fabricating a color filter by which rapid non-uniformity of thickness in a partial region of a color filter is removed, the thickness of ink is made uniform and a perception of color by a viewer is improved.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a method of fabricating a color filter using an ink-jet technique, the method including inclining an ink-jet head having a plurality of nozzles at a predetermined angle, moving the ink-jet head in a lengthwise direction of the color filter that is divided into a plurality of working regions, ejecting color ink into a plurality of pixels, moving the ink-jet head to another adjacent working region after a work in a predetermined working region is completed, and ejecting color ink, wherein the ink-jet head passes over a working region in which all of the nozzles of the ink-jet head operate and color ink is ejected through each of the nozzles or the ink-jet head leaves the working region so that, when color ink is ejected into the pixel, all of the nozzles operate.

The foregoing and/or other aspects and utilities of the present general inventive concept may also be achieved by providing a method of fabricating a color filter using an ink-jet technique, the method including inclining an ink-jet head having a plurality of nozzles at a predetermined angle, moving the ink-jet head along an upper portion of a mother glass that is defined into a plurality of color filters and a region between the plurality of color filters, ejecting color ink into a plurality of pixels disposed in a predetermined color filter, moving the ink-jet head to the another color filter after work of the predetermined color filter is completed, and ejecting color ink, wherein, when the ink-jet head moves to the another adjacent color filter from the predetermined color filter, the ink-jet head moves while all of the nozzles of the ink-jet head operate in a region between the predetermined color filter and the adjacent color filter and color ink is ejected through each of the nozzles.

The foregoing and/or other aspects and utilities of the present general inventive concept may also be achieved by providing a method of fabricating a color filter using an ink-jet technique, the method including inclining an ink-jet head having a plurality of nozzles at a predetermined angle with respect to a color filter having a plurality of work regions with pixels in which to eject ink therein and blank regions and moving the ink-jet head in a lengthwise direction of the color filter while ejecting ink from each of the plurality of nozzles continuously while each of the plurality of nozzles of the ink-jet head moves across the entire length of the color filter.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 illustrates an example of a method of fabricating a color filter by ejecting ink into each pixel of the color filter using a conventional ink-jet head;

FIG. 2 illustrates the color filter fabricated by the method of FIG. 1 that is divided into regions according to ink thickness;

FIG. 3 is a graph illustrating an ink thickness taken along line I-I′ of FIG. 2;

FIG. 4 is a graph illustrating an ink thickness taken along line II-II′ of FIG. 2;

FIG. 5 illustrates a method of fabricating a color filter using an ink-jet technique according to an embodiment of the present general inventive concept; and

FIG. 6 illustrates a method of fabricating a color filter using an ink-jet technique according to another embodiment of the present general inventive concept.

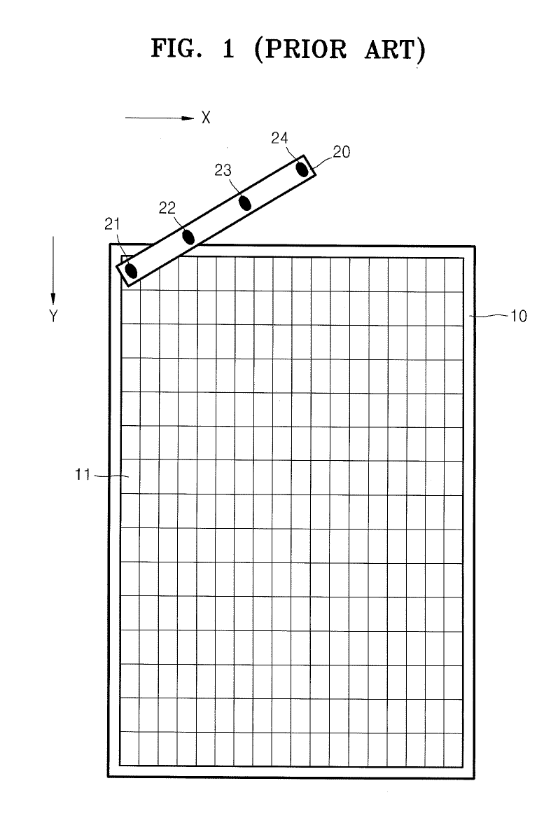

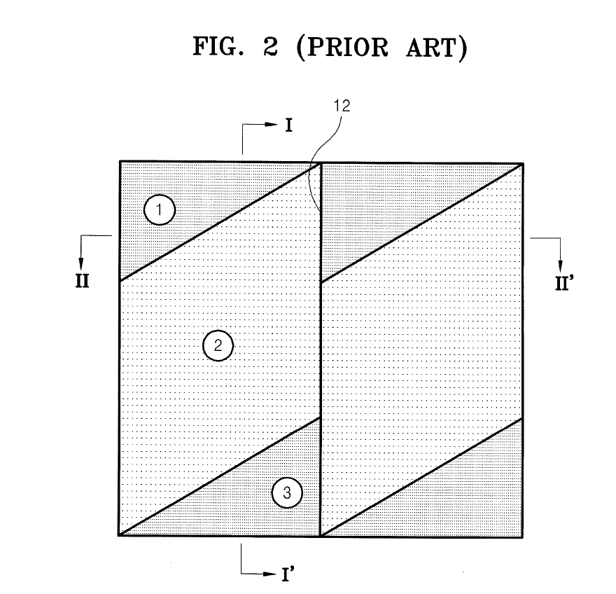

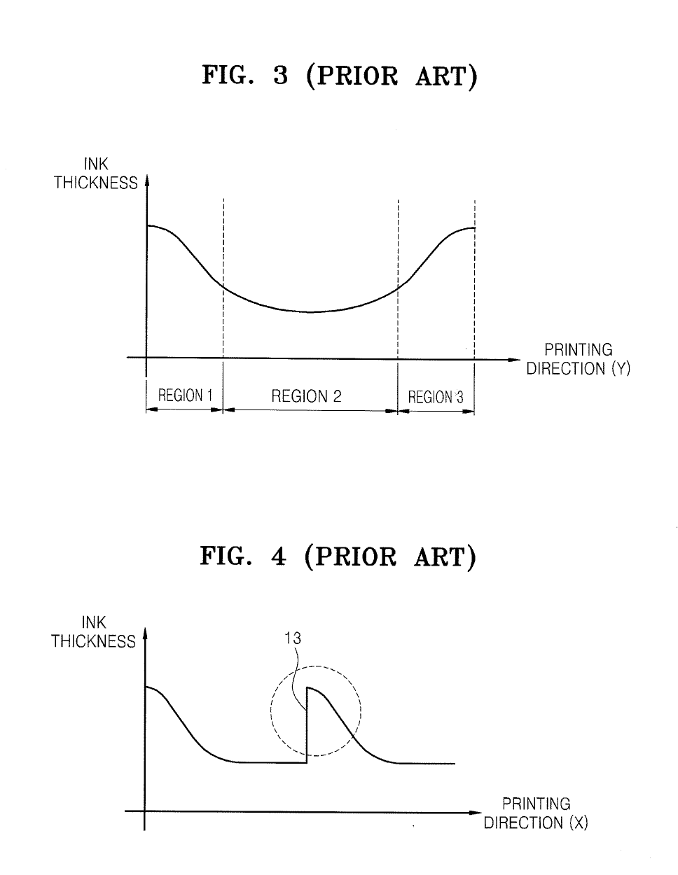

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

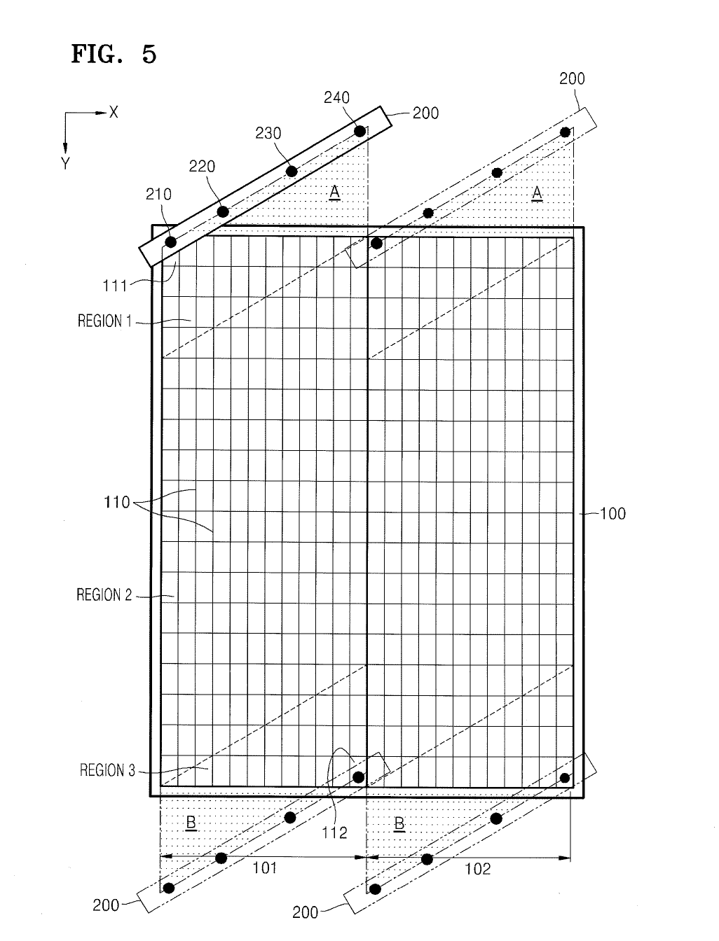

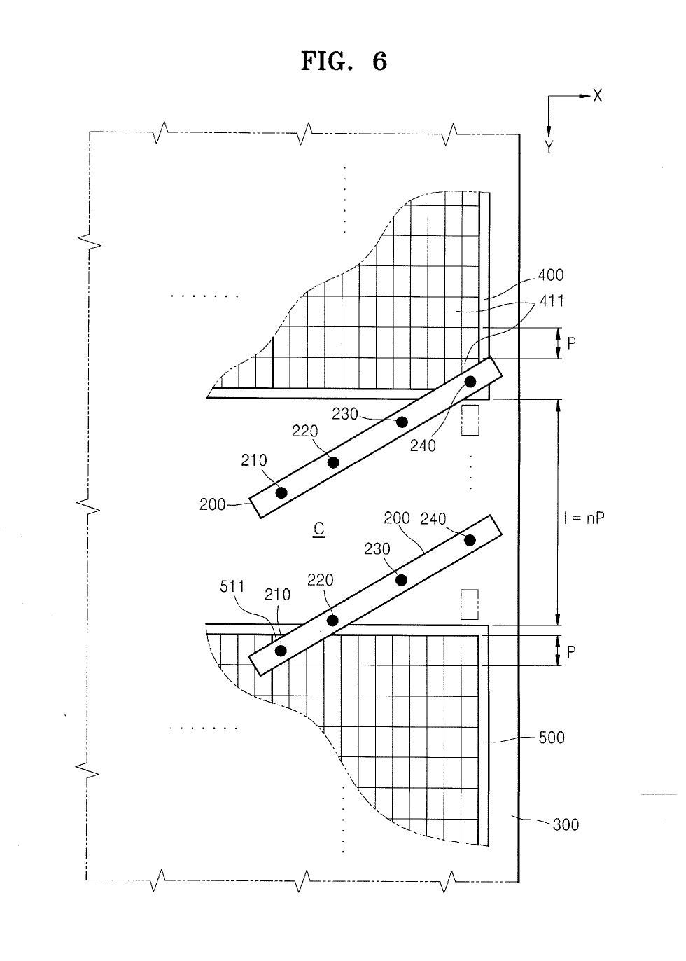

FIG. 5 illustrates a method of fabricating a color filter using an ink-jet technique according to an embodiment of the present general inventive concept, and FIG. 6 illustrates a method of fabricating a color filter using an ink-jet technique according to another embodiment of the present general inventive concept.

Referring to FIG. 5, a color filter 100 can include a plurality of pixels 111 defined by a black matrix 110. Red, green, and blue colors are sequentially filled in the pixels 111 and therefore, a pixel is formed.

An ink-jet head 200 comprises four nozzles 210, 220, 230, and 240, and the ink-jet head 200 ejects ink into the pixels 111 by moving along an upper portion of the color filter 100 in a lengthwise direction (Y-direction) of the color filter 100 while the ink-jet head 200 is inclined at predetermined angle with respect to the color filter 100. The number of nozzles disposed in the ink-jet head 200 is not limited to the number illustrated in the drawings and may include more nozzles than the number illustrated.

The color filter 100 is divided into a plurality of working regions 101 and 102. Making the length of the ink-jet head 200 small and dividing of the color filter 100 into the plurality of working regions 101 and 102 is done to improve working conveniences because there is a limitation in making the length of the ink-jet head 200 large. Thus, after work of the working region 101 is completed using the ink-jet head 200, the same work is performed in the other adjacent working region 102. The number of working regions may be changed according to the size of the color filter 100 and the length of the ink-jet head 200.

When the ink-jet head 200 moves to the upper portion of the color filter 100 along the lengthwise direction (Y-direction) of the color filter 100, all of the nozzles 210, 220, 230, and 240 operate in region 1 through 3 and color ink is ejected through the nozzles 210, 220, 230, and 240.

When the nozzle 210 of the ink-jet head 200 passes over the pixel 111 of the color filter 100 and color ink is ejected through the nozzle 210, other nozzles 220, 230, and 240 also operate simultaneously so that color ink can be ejected through the nozzles 220, 230, and 240, respectively. Thus, when the nozzle 210 passes over the pixel 111, all of the nozzles 210, 220, 230, and 240 operate and color ink is ejected through the nozzles 210, 220, 230, and 240. As a result, in a region A which is positioned outside the color filer 100, color ink is ejected through the nozzles 220, 230, and 240, respectively.

In addition, other nozzles 210, 220, and 230 operate continuously even when they are sequentially separated from the color filter 100 until the nozzle 240 is separated from the color filter 100. Thus, as long as the nozzle 240 is positioned in the pixel 112 of the color filter 100, all of the nozzles 210, 220, 230, and 240 operate and color ink is ejected through each of the nozzles 210, 220, 230, and 240, respectively. As a result, in a region B which is positioned outside the color filer 100, color ink is ejected through the nozzles 210, 220, and 230, respectively.

Since color ink is unnecessarily ejected in region A and B and should not remain in these regions, color ink is prevented from being stained in region A and B of an actual color filter by using a tape in these regions. Thus, after region A and B is taped and color ink is entirely ejected, the tape is removed from region A and B so that contamination can also be prevented from the color ink.

Thus, in a method of fabricating a color filter using an ink-jet technique according to an embodiment of the present general inventive concept, when color ink is ejected into the pixel 111 of the color filter 100, all of the nozzles 210, 220, 230, and 240 of the ink-jet head 200 operate and color ink is ejected through the nozzles 210, 220, 230, and 240, respectively, so that an effect caused by cross-talk can be reduced.

Referring to FIG. 6, a color filter defines a mother glass into a plurality of color filters 400 and 500 and a region C positioned therebetween so as to realize mass production, and a plurality of pixels 411 and 511 are disposed in each of the colorfilters 400 and 500. Thus, the ink-jet head (see 200 of FIG. 5) moves and color ink is ejected into a pixel 411 of one color filter 400 and is filled therein, and the ink-jet head moves to the other adjacent color filter 500 and a pixel 511 is filled with color ink from the ink-jet head 200.

When the ink-jet head 200 moves to the upper portion of region C along the lengthwise direction (Y-direction) of the color filter 100, all of the nozzles 210, 220, 230, and 240 operate and color ink is ejected through the nozzles.

Other nozzles 210, 220, and 230 operate continuously even when they are sequentially separated from the color filter 400 until the nozzle 240 of the ink-jet head 200 is separated from the pixel 411 of the color filter 400. Thus, even when the nozzle 240 is positioned in the pixel 411 of the color filter 400 and other nozzles 210, 220, and 230 are positioned in the region C, all of the nozzles 210, 220, 230, and 240 operate and color ink is ejected through the nozzles 210, 220, 230, and 240, respectively. As a result, in the region C which is positioned outside the color filer 400, color ink is ejected through the nozzles 210, 220, 230, and 240, respectively.

In addition, when the nozzle 210 of the ink-jet head 200 passes over the pixel 511 of the color filter 500 and color ink is ejected through the nozzle 210, other nozzles 220, 230, and 240 also operate simultaneously so that color ink can be ejected through the nozzles 220, 230, and 240. Thus, when the nozzle 210 passes over the pixel 511, all of the nozzles 210, 220, 230, and 240 operate so that color ink can be ejected through the nozzles 210, 220, 230, and 240, respectively. As a result, in region C which is positioned outside the color filer 500, color ink is ejected through the nozzles 210, 220, 230, and 240, respectively.

To this end, the length in a Y-direction of the region C may be an integer multiple of a pitch P in a Y-direction of the pixels 411 and 511. That is, I=nP may be satisfied. This is because, even when the ink-jet head 200 moves along the Y-direction, is separated from the color filter 400, passes the region C and passes over the color filter 500, the ink-jet head 200 can pass over the color filter 500 while all of the nozzles 210, 220, 230, and 240 operate at all times.

Meanwhile, each of the color filters 400 and 500 is filled with color ink ejected using the method of FIG. 5.

Thus, in the method of fabricating a color filter using an ink-jet technique according to the present embodiment, color ink is ejected into the pixel of the color filter 100 and all of the nozzles 210, 220, 230, and 240 of the ink-jet head 200 operate and color ink is ejected through the nozzles 210, 220, 230, and 240, respectively, even in a region between color filters so that an effect caused by cross-talk can be reduced.

As described above, the methods of fabricating a color filter using an ink-jet technique according to the above-described embodiments has the following effects. When color ink is ejected into a color filter, all nozzles operate such that an effect caused by cross-talk is minimized. Further, all nozzles operate even in a region between a plurality of color filters such that an effect caused by cross-talk is minimized.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A method of fabricating a color filter using an ink-jet technique, the method comprising:
inclining an ink-jet head having a plurality of nozzles at a predetermined angle;
moving the ink-jet head in a lengthwise direction of the color filter that is divided into a plurality of working regions;
ejecting color ink into a plurality of pixels;
moving the ink-jet head to another adjacent working region after work in a predetermined working region is completed; and
ejecting color ink,
wherein the ink-jet head passes over a working region in which all of the nozzles of the ink-jet head operate and color ink is ejected through each of the nozzles, and when the ink-jet head leaves the working region so that color ink is ejected into the pixels by less than all of the plurality of nozzles, all of the nozzles continue to operate.

2. A method of fabricating a color filter using an ink-jet technique, the method comprising:
inclining an ink-jet head having a plurality of nozzles at a predetermined angle;
moving the ink-jet head along an upper portion of a mother glass that is defined into a plurality of color filters and a region between the plurality of color filters;
ejecting color ink into a plurality of pixels disposed in a predetermined color filter;
moving the ink-jet head to another color filter after work of the predetermined color filter is completed; and
ejecting color ink,
wherein, when the ink-jet head moves to another adjacent color filter from the predetermined color filter, the ink-jet head moves while all of the nozzles of the ink-jet head operate in a region between the predetermined color filter and the adjacent color filter and color ink continues to be ejected through each of the nozzles.

3. The method of claim 2, wherein the length of the region between the predetermined color filter and the adjacent color filter is an integer multiple of a pitch of the pixel.

4. The method of claim 2, wherein the ink-jet head passes over or leaves each color filter region while all of the nozzles of the ink-jet head operate and color ink is ejected through each of the nozzles.

5. A method of fabricating a color filter using an ink-jet technique, the method comprising:
inclining an ink-jet head having a plurality of nozzles at a predetermined angle with respect to a color filter having a plurality of work regions with pixels in which to eject ink therein and blank regions; and
moving the ink-jet head in a lengthwise direction of the color filter while ejecting ink from each of the plurality of nozzles continuously while each of the plurality of nozzles of the ink-jet head moves across the entire length of the color filter.
